(19) United States
(12) Patent Application Publication
(10) Pub. No.: US 2006/0272941 A1
(43) Pub. Date: Dec. 7, 2006

(54) Large area elastomer bonded sputtering target and method for manufacturing

(76) Inventors: Wayne R. Simpson, San Jose, CA (US); Ryan A. Scatena, Gilroy, CA (US); Thomas R. Stevenson, Gilroy, CA (US)

Correspondence Address: DONALD J. PAGEL, 586 NORTH FIRST STREET, SUITE 207, SAN JOSE, CA, 95112, US

(21) Appl. No.: 11/147,105

(22) Filed: Jun. 6, 2005

(51) Int. Cl. C23C 14/00

(52) U.S. Cl. 204/298.12; 204/192.12

(57) ABSTRACT

The present invention includes an assembly comprised of a large sputtering target attached to a backing plate by an elastomer, such as a silicone elastomer, and a method for attaching the large sputtering target to the backing plate using the elastomer as an attachment layer. The method of the present invention comprises the steps of applying a quantity of the elastomer to the backing plate and/or to the sputtering target, where the sputtering target has a sputtering surface having a surface area greater than 6600 square centimeters. The backing plate and the sputtering target are then brought together either with or without a thermal transfer member positioned between the backing plate and the sputtering target.

### BACKGROUND OF THE INVENTION

1. Technical Field

The present invention relates to a method for manufacturing a large sputtering target for use in a vacuum deposition technique and more particularly to a method for attaching the large sputtering target to a backing plate using an elastomer.

2. Background Information

Sputtering is a major vacuum deposition technique used to deposit a thin film of a target material on a substrate. Many materials are capable of being sputtered and typical target materials include elemental metals (such as copper, gold, tungsten, molybdenum and aluminum etc.), alloys (such as aluminum-copper alloy, aluminum-neodymium and titanium-tungsten alloy, etc.), and compounds (such as silicon dioxide and titanium nitride, etc.). Typical substrates on which the target material is deposited include items such semiconductor devices, compact discs (CD), hard disks for use in magnetic disk drives, and optical devices such as flat panel displays.

A typical sputtering apparatus comprises a vacuum chamber inside of which are positioned the target and the substrate. The target is electrically configured to be an electrode with a large ion flux. The chamber is filled with an inert gas which ionizes when power is supplied to the target/electrode. The positively charged inert gas ions collide with the target causing atomic sized particles to be ejected from the target. The particles are then deposited on the surface of the substrate as a thin film.

Because of this electrical configuration, the target can become very hot and needs to be cooled. In a typical sputtering apparatus, the cooling is provided by a water-cooled backing plate which is attached to the backside of the target by an attachment layer. FIG. 1 illustrates a typical sputtering target assembly 10 comprised of a sputtering target 12, a backing plate 16 and an attachment layer 20. The sputtering target has a sputtering face 24 which is generally a planar surface from which the material to be sputtered on the substrate can be ejected. The sputtering target 12 can be one continuous piece of material, or it can be comprised of two or more separate pieces (tiles). FIG. 2 illustrates a typical water-cooled backing plate.

A number of materials are used in the attachment layer 20 to attach the target 12 to the backing plate 16. A common technique is to use a metal or metal alloy, such as indium or tin for attaching the target to the backing plate. Elastomeric materials have also been used for bonding the sputtering target to the backing plate. However, in the prior art only relatively small sputtering targets have been bonded. In these sputtering targets the surface area of the sputtering face for targets bonded with elastomers is less than approximately five hundred and twenty-five square inches (525 in²). A similar technique is used to bond the electrode assembly in a plasma reaction chamber. For example, in U.S. Pat. No. 6,194,322, Lilleland et al. describes a technique for bonding an electrode to a support member in a plasma reaction chamber that utilizes an elastomeric joint.

A trend in the manufacturing of flat panel displays and other devices is to manufacture many devices on a very large substrate, much like smaller semiconductor devices are manufactured on wafers. For example, flat panel display manufacturers would like to be able to process square or rectangular flat panel display substrates having surface areas on the order of 1000 square inches (6600 square centimeters) to 6000 square inches (38,700 square centimeters) or more. Some of these large substrates are currently being processed using indium bonding technology. However, in preparing a sputtering target large enough to process these substrates, the problem of warping occurs when indium is used as the attachment layer to attach the target to the backing plate. The warping is due to the different coefficients of thermal expansion that exist for the indium and the target and/or backing plate. Therefore, an improved bonding method for large sputtering targets is needed.

### SUMMARY OF THE PRESENT INVENTION

Briefly, the present invention includes an assembly comprised of a large sputtering target attached to a backing plate by an elastomer, and a method for attaching the large sputtering target to the backing plate using an elastomer attachment layer. The method of the present invention comprises the steps of applying a quantity of the elastomer to the backing plate and/or to the sputtering target, where the sputtering target has a sputtering surface having a surface area greater than 6600 square centimeters. The backing plate and the sputtering target are then brought together, either with or without a thermal transfer member positioned between the backing plate and the sputtering target. If the thermal transfer member is used, it becomes at least partially coated with the elastomer when the backing plate and the sputtering target are then brought together. The surface area of the sputtering target refers to the total area of the sputtering surface in a single assembly, regardless of whether the sputtering target is comprised of one piece of material or more than one piece. Additionally, in the preferred embodiment, the sputtering target includes a mating surface which also has a surface area greater than 6600 square centimeters and which is substantially covered with the elastomer.

### BRIEF DESCRIPTION OF THE SEVERAL VIEWS OF THE DRAWINGS

FIG. 1 is an isometric view of a sputtering target assembly;

FIG. 2 is an isometric view of a of prior art backing plate;

FIG. 3 is an isometric view of a sputtering target assembly;

FIG. 4 is a cross sectional view of a sputtering target assembly;

FIG. 5 is an exploded view of a sputtering target assembly according to the present invention; and

FIG. 6 is a side view of a spring fixture.

### DETAILED DESCRIPTION OF THE INVENTION

In the present invention, the sputtering target assembly 10 comprises the sputtering target 12, the backing plate 16 and the attachment layer 20. The sputtering target 12 includes the sputtering surface 24 which is a surface from which the material to be sputtered on the substrate can be ejected when the sputtering process begins. In the present invention, the sputtering surface 24 has a surface area greater than 6600 square centimeters (approximately 1025 in²) and the attachment layer 20 comprises an elastomer. As used herein, the surface area of the sputtering surface 24 refers to the total area of the sputtering surface in a single assembly 10, regardless of whether the sputtering target is comprised of one piece of material or more than one piece.

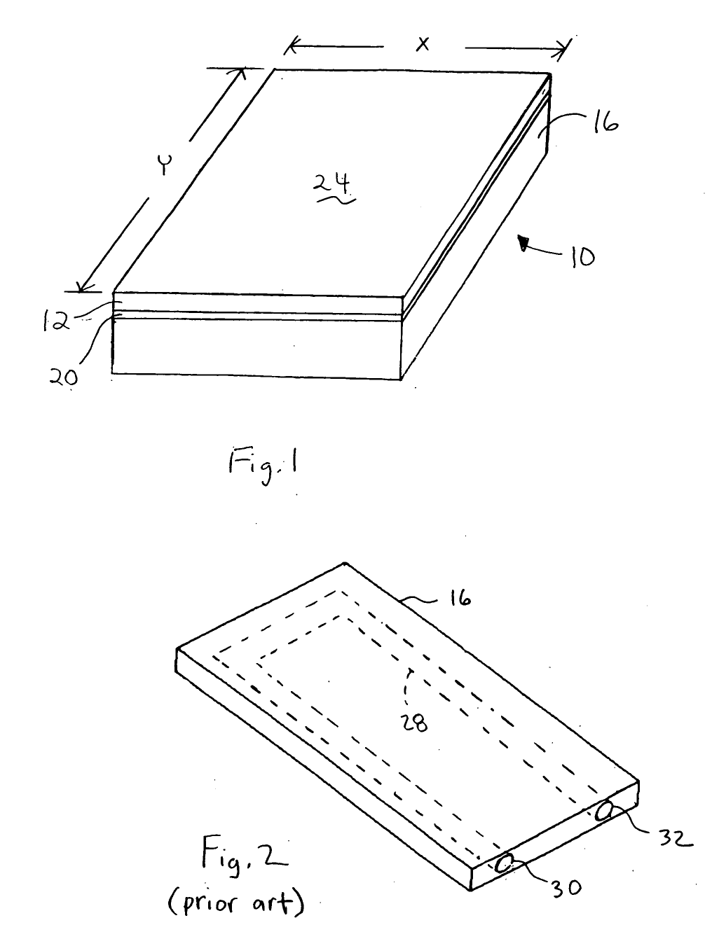

As shown in FIG. 1, for a rectangular shaped sputtering assembly 10, the sputtering surface 24 has a width x and a length y, and the surface area of the sputtering surface 24 is the product of the width x and the length y. The sputtering target and sputtering surface can have other shapes, such as a square, a triangle, or another type of polygon shape, or a circular or oval shape. In such cases, the surface area of the sputtering surface is calculated using another suitable geometric formula for area.

The sputtering target 12 can be comprised of many materials. Typical sputtering target materials include elemental metals (such as copper, gold, tungsten, molybdenum and aluminum etc.), alloys (such as aluminum-copper alloy, aluminum-neodymium and titanium-tungsten alloy, etc.), and compounds (such as silicon dioxide, ceramics and titanium nitride, etc.).

FIG. 3 illustrates an assembly 10 where the sputtering target 12 comprises a plurality of tiles 34. Each of the tiles 34 are comprised of material to be sputtered. In the preferred embodiment each of the tiles 34 are comprised of the same substance (i.e. have the same chemical composition), although in alternative embodiments they could have different compositions. Each of the tiles 34 have an individual sputtering surface 36 and all of the individual sputtering surfaces 36 are positioned to be in approximately the same plane. Therefore, in FIG. 3, the surface area of the sputtering surface 24 is the sum of the surface areas of the individual sputtering surfaces 36. In a preferred embodiment, each of the individual sputtering surfaces 36 has the same dimensions (width m and length n) and hence the same individual surface area (m times n), but in alternative embodiments the sputtering surfaces 36 could have different surface areas.

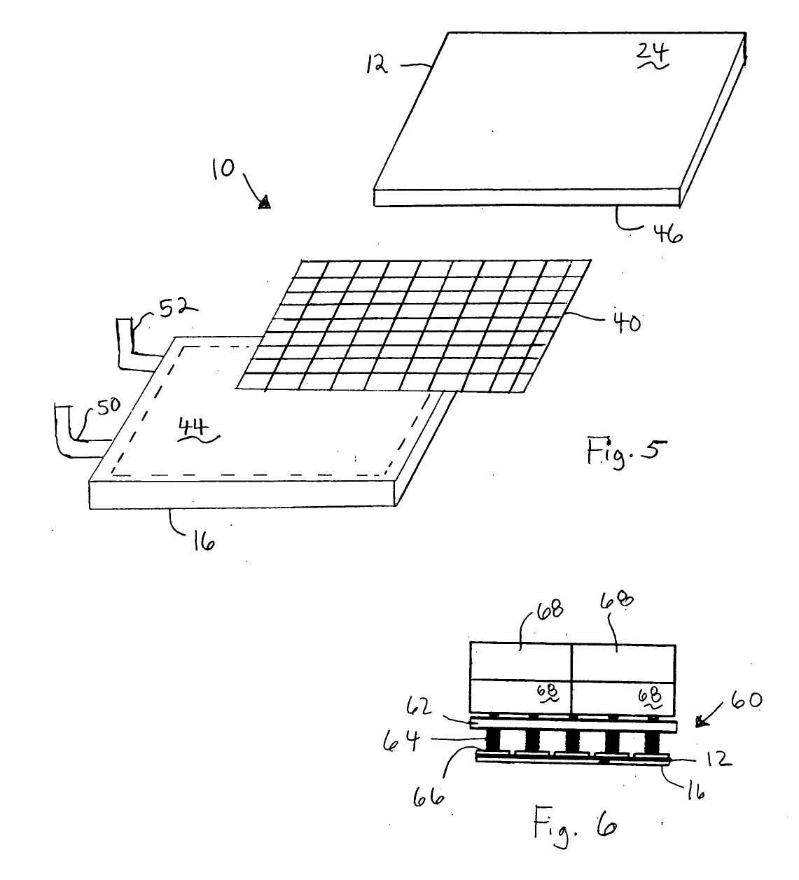

In FIG. 3, a plurality of spaces 37 exist between the tiles 34. The spaces 37 could cause contamination of the substrate if the spaces 37 allow the attachment layer 20 to be exposed during the sputtering process. For example, material in the attachment layer, such as metal from the thermal transfer member 40 (shown in FIG. 5) could be inadvertently sputtered onto the substrate. In the preferred embodiment, this type of contamination is prevented by positioning a filler material 38 in or over at least part of the space 37. Preferably, the filler material has the same composition as the sputtering surfaces 36. However, in alternative embodiments, the filler material could comprise a material that doesn't contaminate the substrate, such as silicon or SiO₂. The filler material 38 covers the part of the attachment layer 20 that is positioned underneath the space 37 and prevents inadvertent sputtering of the attachment layer.

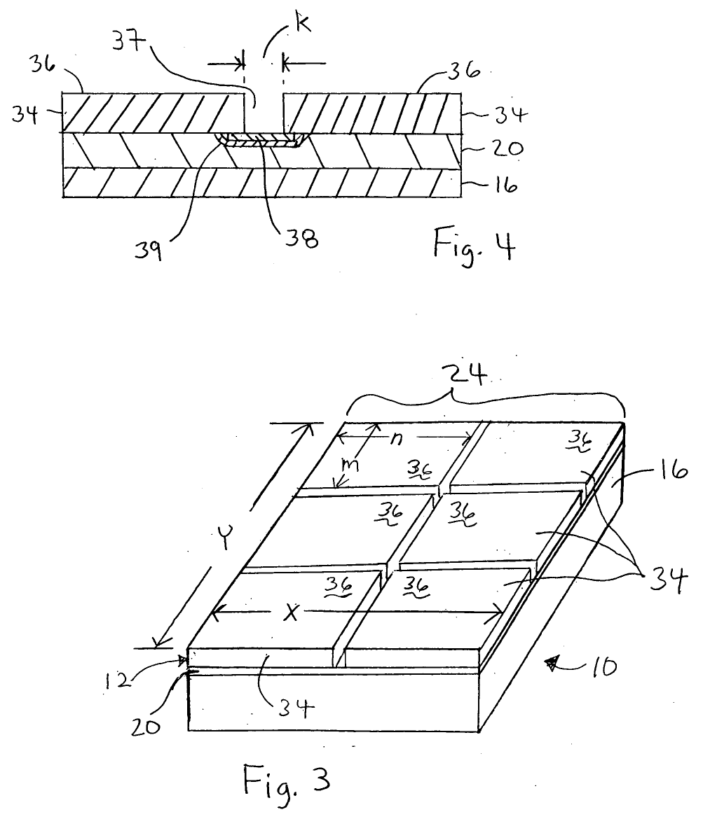

FIG. 4 illustrates the filler material 38 positioned over an end of the space 37 and covering the part of the attachment layer 20 that is positioned underneath the space 37. In a preferred embodiment, the filler material 38 comprises a foil comprised of a metal or metal alloy that has the same composition as the sputtering surface 36. For example, if the sputtering surfaces 36 (and the tiles 34) are comprised of aluminum, then the filler material would comprise an aluminum foil. Then if any of the filler material is sputtered onto the substrate, it does not represent a contaminant. In FIG. 4, the filler material (foil) 38 is held in place by a piece of tape 39. In a representative embodiment, the space 37 has a width k. A typical range for the width k is 0.02 to 0.06 inches.

The method and apparatus of the present invention comprise sputtering targets with a large sputtering surface 24. In a preferred embodiment, the sputtering surface has a surface area greater than sixty-six hundred square centimeters (6600 cm²). In another embodiment, the sputtering surface is greater than twenty-two thousand square centimeters (22,000 cm²) and may be seventy thousand square centimeters (70,000 cm²) or larger.

In the present invention, the large sputtering targets are attached to the backing plate with an elastomer attachment layer. As used herein, an elastomer is a substance (preferably a polymer) having elastic properties that resemble natural rubber. In a preferred embodiment, the elastomer comprises a silicone elastomer, and more preferably comprises a poly(dimethylsiloxane) elastomer, such as Sylgard® 184 brand silicone elastomer sold by Dow Corning. Silicone is a polymeric elastomer containing a silicon-oxygen (Si—O) backbone and poly(dimethylsiloxane) or PDMS is a silicone elastomer comprised of a Si—O—Si backbone with each silicon atom bearing two methyl (Me) groups. PDMS is typically denoted as (Me₂SiO)ₙ.

Other types of suitable elastomers can be used as the attachment layer 20 such as polymers compatible with a vacuum environment that can withstand temperatures above 50° C. while maintaining a suitably strong bond between the sputtering target and the backing plate and adequately transferring heat from the sputtering target to the backing plate. Specific types of polymers that can be used include polyimide, polyketone, polyetherketone, polyether sulfone, polyethylene terephthalate, and fluroethylene propylene copolymers. Flexible epoxy or rubber can also be used Other silicone elastomers that can be used include the products marketed as General Electric RTV 31 and General Electric RTV 615 brand silicone elastomers.

During operation, the sputtering target can reach temperatures of 50 to 250° C. or greater. In order to remove heat from the sputtering target, backing plates are usually water cooled, as is well-known in the prior art. FIG. 2 illustrates a prior art backing plate 16 having a passage 28 bored inside of it. Water enters the passage 28 through an inlet 30 and exits through an outlet 32.

In order to facilitate the transfer of heat from the sputter target 12 to the backing plate 16, the attachment layer 20 may optionally include a thermal transfer member 38. The thermal transfer member helps conduct heat from the sputtering target and moves it to the backing plate. In a preferred embodiment, the thermal transfer member comprises one or more pieces of a metal mesh at least partially embedded in the elastomeric material. For example, one or more pieces of copper screen may be used as the thermal transfer member.

In such an embodiment, the thickness of the screen controls the thickness of the attachment layer. This means that the surface of the screen may protrude through the elastomer in places and be in physical contact with the mating face of the sputtering target and/or the mating face of the backing plate. In other places, a thin layer of elastomer may be positioned between the screen and the mating face of the sputtering target and/or the mating face of the backing plate. However, the screen still transfers heat in these regions because the elastomer has sufficient thermal conductivity to allow the heat to pass. Typically, the screen has a thickness of two thousandths to sixty thousandths of an inch (0.002 to 0.060 inches) or more, so the thickness of the attachment layer 20 is in this range. Many mesh sizes for the screen can be used, but twenty-two mesh to one hundred mesh (22 mesh to 100 mesh) is a representative range of mesh sizes. Other mesh sizes can be used depending on the design of the assembly 10.

Preferably, the thermal transfer member 38 is also electrically conductive. This is because the sputtering target 12 acts as an electrode and the electrical connection for the electrode is usually made to the backing plate 16. Therefore electrical current must pass between the sputtering target 12 and the backing plate 16, preferably across the whole area that comprises the mating surfaces of the sputtering target 12 and the backing plate 16. Imbedding a metal screen in the attachment layer 20 improves the electrical conductivity of the attachment layer 20. This is especially true in regions where the surface of the screen protrudes through the elastomer and is in physical contact with the mating face of the sputtering target and/or the mating face of the backing plate.

To further improve the thermal and/or electrical conductivity of the attachment 20 layer, a thermally and/or electrically conductive powder or particulate substance, such as a metal powder can be mixed with the elastomer before it cures. In a preferred embodiment, the metal powder is aluminum powder, but other thermally and/or electrically conductive powders, including other metal powders, may be used. In the preferred embodiment, the main purpose of the conductive powder is to improve the thermal conductivity of the attachment layer. The conductive powder also increases the viscosity of the elastomer. In alternate embodiments, the attachment layer 20 can be used without the thermal transfer member (i.e. without the thermally and/or electrically conductive screen). In such an embodiment, the attachment layer needs to be as thin as possible so that thermal and/or electrical transfer can occur through the elastomer in the attachment layer.

In a preferred embodiment, the method for attaching the sputtering target 12 to the backing plate 16 comprises the steps of applying a quantity of an elastomer to the backing plate and to the sputtering target, with the sputtering target having a sputtering surface 24 that has a surface area greater than 6600 square centimeters. The backing plate and the sputtering target are then brought together with a thermal transfer member (if used) being positioned between the backing plate and the sputtering target so that the thermal transfer member becomes at least partially coated with the elastomer. The phrase “at least partially coated” means that regions of the thermal transfer member (e.g. the copper screen) may be protruding through the elastomer layer and making direct contact with a mating surface on the backing plate and/or the sputtering target.

In alternate embodiments, a quantity of elastomer can be applied to a mating surface on either the backing plate or the sputtering target, but not both. The backing plate and the sputtering target are then brought together with enough pressure to evenly distribute the elastomer on the mating surface which initially was free of elastomer. If a thermal transfer member is used, it is positioned between the backing plate and the sputtering target before they are brought together.

FIG. 5 illustrates the relative orientations of the sputtering target 12, the backing plate 16 and a thermal transfer member 40. The backing plate has a mating surface 44 to which a quantity of elastomer will be applied, preferably as a uniform layer. In some embodiments, mating surface 44 extends completely to the edges of the backing plate. In other embodiments, the mating surface is recessed slightly from the edges of the backing plate as is indicated in by the dashed line on the backing plate 16 in FIG. 5. In either type of embodiment, the mating surface 44 is the flat area of the backing plate that will be covered with elastomer.

Similarly, the sputtering target has a mating surface 46 to which a quantity of elastomer will be applied, preferably as a uniform layer. The mating surface 46 may or may not be recessed in the same manner as was described above for the mating surface 44, and the mating surface 46 is the flat area of the sputtering target that will be covered with elastomer. The mating surfaces 44 and 46 will face each other when the sputtering assembly 10 is assembled, and the thermal transfer member 40 (if used) will be positioned between the two mating surfaces 44 and 46. A pair of fixtures 50 and 52 are attached to the backing plate. The fixture 50 fits into the inlet 30 (shown in FIG. 2) in the backing plate 16 to allow water or some other fluid to be introduced into the passage 28 in a controlled manner. The fixture 52 fits into the outlet 32 (shown in FIG. 2) to allow water or other fluid to flow out of the passage 28 in a controlled manner.

In FIG. 5, the mating surface 46 of the sputtering target has the same width x and length y (shown in FIGS. 1 and 3) as the sputtering surface 24 (when the mating surface 46 is not recessed from the edge). Therefore, the area of the mating face 46 in this case is given by the product (xy) for a rectangular-shaped sputtering target. If the mating surface 46 is recessed, then the surface area of the mating surface is slightly less than the surface area of the sputtering surface 24. In any case, since the surface area of the sputtering face 24 is greater than 6600 square centimeters, the surface area of the mating surface 46 is also greater than 6600 square centimeters. Additionally, in a preferred embodiment, the mating surface 46 is substantially covered with the elastomer after the assembly 10 is formed. Substantially covered means that the mating surface 46 is covered with elastomer except is small regions such as where the thermal transfer (screen) member makes direct contact with the mating face 46. Furthermore, in other embodiments, the surface area of the mating surface 46 is greater than twenty-two thousand square centimeters (22,000 cm²) and may be seventy thousand square centimeters (70,000 cm²) or larger.

Because the present invention relates to large sputtering targets, mechanical means for moving the large sputtering target and/or the backing plate are needed. In this respect, a heavy lifting mechanism such as an overhead crane with an electric motor capable of lifting one hundred and fifty to five thousand (150-5000) pound loads or more is useful. Typically, a fixture having a plurality of vacuum attachment (suction cup) arms is attached to the heavy lifting mechanism for lifting and manipulating the sputtering target and/or the backing plate. The elastomer is prepared for use and is applied to the mating surfaces 44 and 46. Preferably, the elastomer is applied to the mating surfaces at approximately the same time, but since the elastomer does not cure quickly, it can be applied to one piece and then to the other in any sequence. The heavy lifting mechanism is then used to bring the backing plate and the sputtering target together with the thermal transfer member (if used) positioned between them. The step of bringing the backing plate and the sputtering target together can be accomplished in any number of ways, such as by keeping one piece fixed and moving the other piece, by moving both pieces, or by some other sequence of events.

To promote the uniform formation of the attachment layer, a force is applied to the assembly 10 after the backing plate and the sputtering target have been brought together. The force is directed in a manner that presses the mating surfaces 44 and 46 together. In a preferred embodiment, this is accomplished by positioning the backing plate on a flat surface and evenly distributing weights on the sputtering target over the sputtering surface 24. The goal is to achieve an attachment layer 20 that has a uniform thickness and even distribution after the elastomer has cured. Typically, about two to three pounds per square inch (2-3 psi) of force will yield a suitable attachment layer.

FIG. 4 illustrates a spring fixture 60 for evenly distributing the weight on the sputtering target. The spring fixture 60 comprises platform 62, a plurality of leg members 64, and a plurality of foot members 66, with on foot member 66 being attached to each leg member 64. Preferably, the leg members 64 comprise heavy duty springs. After the spring fixture is positioned on the sputtering target with the foot members 66 resting on the sputtering surface 24, a plurality of sand bags 68 are stacked on the platform 62 to provide the force.

After the force has been applied to the assembly 10, a period of time is allowed to pass so that the elastomer can cure. Curing refers to a chemical process in which the elastomer solidifies, thereby forming the attachment layer 20 which is strong enough to hold the backing plate 16 and the sputtering target 12 together. The time required for curing varies for different elastomers, but typically is in the range of from twenty-four hours to as long as a week. As a general rule, the application of heat to the attachment layer will accelerate the curing process. In a preferred embodiment, heat is supplied to the attachment layer 20 by running hot water into the inlet 30 and out of the outlet 32. However, many other methods for supplying heat to the attachment layer can be used, such as with a large hot plate, a large oven or by covering the assembly 10 with one or more heating pads. Alternatively, the elastomer can be left to cure at room temperature.

After the attachment layer 20 has formed (i.e. after curing), the integrity of the attachment layer can be checked. In a preferred embodiment this is done as follows: The weights 68 and spring fixture 60 are removed from the sputtering assembly and the flow of hot water is replaced with a flow of room temperature water. An infrared camera is focused on the sputtering surface and used to view/film the cool down of the sputtering assembly. If the attachment layer is properly formed, the whole surface should cool down at a uniform rate. Hot spots in the assembly 10 indicate voids and/or regions of nonuniform thicknesses in the attachment layer 20 which may require that the assembly 10 be disassembled and reattached. Voids are typically caused by air gaps in the attachment layer. Of course, many other methods for checking the integrity of the attachment layer are possible. Furthermore, the integrity check may be skipped completely.

In general terms, the method of the present invention can be summarized as comprising the two steps of: 1) applying a quantity of an elastomer to a backing plate and/or to a sputtering target, the sputtering target having a sputtering surface that has a surface area greater than 6600 square centimeters; and 2) bringing the backing plate and the sputtering target together either with or without a thermal transfer member positioned between the backing plate and the sputtering target, so that the thermal transfer member (if it is used) becomes at least partially coated with the elastomer. As noted previously, the surface area of the sputtering target refers to the total area of the sputtering surface in a single assembly 10, regardless of whether the sputtering target is comprised of one piece of material or more than one piece. Additionally, in the preferred embodiment, the sputtering target includes the mating surface 46 which also has a surface area greater than 6600 square centimeters and which is substantially covered with the elastomer.

Stated more specifically, the method of the present invention can be summarized as comprising the steps of: 1) applying a first quantity of an elastomer to the mating surface 44 of the backing plate and/or applying a second quantity of the elastomer to the mating surface 46 of the sputtering target, where the sputtering target has a sputtering surface 24 whose surface area is greater than 6600 square centimeters; 2) bringing the mating surface of the backing plate and the mating surface of the sputtering target together with or without a screen member positioned between the mating surface of the backing plate and the mating surface of the sputtering target so that the screen member becomes at least partially coated with the elastomer (if used); and 3) allowing the elastomer to form an elastomer bond that holds the sputtering target to the backing plate. This last step refers to allowing the elastomer to cure and may be accelerated by the application of heat.

In general terms, the sputtering target assembly 10 comprises the sputtering target 12 having the sputtering surface 24 whose surface area is greater than 6600 square centimeters; the backing plate 16; and the elastomer layer 20 positioned between the sputtering target and the backing plate for attaching the sputtering target to the backing plate and for providing thermal conductivity between the sputtering target to the backing plate.

The following example is exemplary of the method of the present invention:

### EXAMPLE

1. A sputtering target having a sputtering surface with a surface in the range of 40,000 to 70,000 square centimeters (40,000 to 70,000 cm²) is cleaned and the sputtering surface is covered with a protective covering such as protective tape. The mating face of the sputtering target is then blasted with SiC (silicon carbide) blasting media at 80 psi. After blasting, the blasted surface (mating face) is scrubbed and the entire target is washed, such as with DI (deionized) water and ultrasonic washing, and then dried.

2. The water inlet/outlet manifold is covered with protective tape and the water manifold is connected to the backing plate. The backing plate is then covered with a protective coating, such as protective tape, but the mating face on the backing plate is left uncovered. The mating face on the backing plate is then blasted with SiC (silicon carbide) blasting media at 80 psi, and the blasted area is cleaned.

3. Bonding fixtures (i.e. blocks to align and/or center the sputtering target on the backing plate) are installed against the sides of the backing plate. The tiles of the sputtering target are laid out on the mating face of the backing plate with the sputtering surface facing up. Shims are placed in the gaps between the tiles and protective tape is placed over the gaps. The shims are stainless steel members to keep the gaps 37 open and are used where the sputtering target is comprised of multiple tiles such as in FIGS. 3 and 4. A vacuum fixture is attached to the sputtering target and the sputtering target is lifted off of the backing plate and flipped over so that the mating surface of the sputtering target is now facing up. Metal foil is placed over the gaps between the tiles and held in place using an inert tape, such as Kapton™ brand polyimide tape (the foil is placed on the mating surface of the sputtering target). In an optional step, a chemical primer may be applied to the mating surfaces of the sputtering target and the backing plate, and to the screen. In a preferred embodiment, a primer such as Dow Corning® P5200 Clear brand primer may be used. Typically, the primer is applied one to four hours before bonding with the elastomer.

4. Several (e.g. four) strips of copper screen are laid out over the mating surface of the sputtering target and trimmed so that the copper screen is recessed from the edge of the sputtering target, such as by approximately 0.25 inches. The screen is then moved away from the sputtering target, blasted on both sides at 45 psi with SiC blasting medium, washed with acetone and air dried.

5. In a preferred embodiment, the elastomer comprises a poly(dimethylsiloxane) elastomer, such as Sylgard® 184 brand silicone elastomer. In such an embodiment, the two-part poly(dimethylsiloxane) elastomer is mixed according to the manufacturers instructions using a 10:1 ratio of the base to the curing agent. A metal powder may be added to increase the thermal conductivity of the elastomer. For example, in some embodiments, aluminium powder (99.5% purity, 325 mesh) is added to the mixture in a volume ratio of from 1:1 to 3:5 metal powder volume to base volume. Of course other ratios may be used depending on the specific materials and applications involved. The elastomer is degassed and equal amounts are spread on the mating surfaces of the sputtering target and backing plate. The thermal promoter (copper screen) is then laid on the elastomer layer on the backing plate, in the same orientation as was previously determined so that the proper recess of the thermal promoter from the edge of the target will be obtained.

6. The sputtering target is now flipped over (using the vacuum fixture) so that the mating surface of the sputtering target faces the thermal promoter laying on the mating surface of the backing plate. The sputtering target and the backing plate are aligned and the sputtering target is lowered onto the backing plate. The vacuum fixture is removed from the sputtering target and a protective mat, such as one or more rubber mats, are placed over the sputtering face. A spring fixture is placed on the sputtering face with the protective mat protecting the sputtering face from the spring fixture, and weights are placed on the spring fixture to apply a downward force on the sputtering assembly. In a representative embodiment, the weights are pallets of sandbags that loaded on the spring fixture with a fork lift. Curing of the elastomer is accelerated by introducing hot water (50-60° C.) into the fluid passages in the backing plate using the water manifold. The flow of hot water is continued for approximately eight hours.

7. After approximately eight hours, the weights and spring fixture are removed from the sputtering assembly, and the flow of hot water is replaced with a flow of room temperature water. An infrared camera is focused on the sputtering surface and used to view and/or film or photograph the cool down of the sputtering assembly. The whole surface should cool down at a uniform rate. Hot spots in the assembly indicate voids (air gaps) and/or nonuniform thickness in the elastomer bonding layer which may require the assembly to be disassembled and reattached. Finally, excess elastomer that has oozed out from the attachment layer is removed from the outside of the sputtering assembly.

Although the present invention has been described in terms of the presently preferred embodiments, it is to be understood that such disclosure is not to be interpreted as limiting. Various alterations and modifications will no doubt become apparent to those skilled in the art after having read the above disclosure. Accordingly, it is intended that the appended claims be interpreted as covering all alterations and modifications as fall within the true spirit and scope of the invention.

We claim:

1. A method for attaching a sputtering target to a backing plate comprising:
applying a quantity of an elastomer to a backing plate and/or to a sputtering target, the sputtering target having a sputtering surface and a mating surface that each have a surface area greater than 6600 square centimeters; and
bringing the backing plate and the sputtering target together so that the mating face of the sputtering target is substantially covered with the elastomer.

2. The method of claim 1 wherein the elastomer comprises a silicone elastomer.

3. The method of claim 2 wherein the silicone elastomer comprises poly(dimethylsiloxane).

4. The method of claim 1 wherein the sputtering surface has a surface area greater than 22,000 square centimeters.

5. The method of claim 1 further comprising:
positioning a thermal transfer member between the backing plate and the sputtering target so that the thermal transfer member is at least partially coated with the elastomer.

6. A method for attaching a sputtering target to a backing plate comprising:
applying a quantity of an elastomer to a mating surface of a backing plate and/or to a mating surface of a sputtering target, the sputtering target having a sputtering surface whose surface area is greater than 6600 square centimeters;
bringing the mating surface of the backing plate and the mating surface of the sputtering target together with a thermal transfer member positioned between the mating surface of the backing plate and the mating surface of the sputtering target so that the thermal transfer member becomes coated with the elastomer; and
allowing the elastomer to form an elastomer bond that holds the sputtering target to the backing plate.

7. The method of claim 6 wherein the thermal transfer member comprises one or more pieces of metal screen.

8. The method of claim 6 wherein a hot fluid is run through the inside of the backing plate to accelerate the formation of the elastomer bond.

9. The method of claim 6 further comprising:
applying heat to the backing plate and/or the sputtering target to accelerate the formation of the elastomer bond; and
recording one or more infrared images of the sputtering target as the sputtering target is allowed to cool down so that the presence of hot spots in the elastomer bond can be detected.

10. The method of claim 6 further comprising:
before allowing the elastomer bond to form, applying a force to the sputtering target to help evenly distribute the elastomer.

11. The method of claim 6 wherein the sputtering surface comprises a plurality of individual sputtering surfaces with each of the individual sputtering surfaces comprising a face of a separate tile.

12. The method of claim 11 further comprising filling a space between two or more of the individual sputtering surfaces with a filler material, the filler material and the two or more individual sputtering surfaces all being comprised of substantially the same substance.

13. The method of claim 12 wherein the filler material comprises a metal foil or a metal alloy foil.

14. The method of claim 6 wherein the elastomer comprises a silicone elastomer.

15. The method of claim 14 wherein the silicone elastomer comprises poly(dimethylsiloxane).

16. The method of claim 6 wherein the sputtering target includes a mating surface that has a surface area greater than 6600 square centimeters and the mating surface is substantially covered with the elastomer.

17. A sputtering target assembly comprised of:
a sputtering target having a sputtering surface whose surface area is greater than 6600 square centimeters;
a backing plate; and
an elastomer layer positioned between the sputtering target and the backing plate for attaching the sputtering target to the backing plate and for providing thermal conductivity between the sputtering target to the backing plate.

18. The sputtering target assembly of claim 17 wherein the elastomer comprises a silicone elastomer.

19. The sputtering target assembly of claim 18 wherein the silicone elastomer comprises poly(dimethylsiloxane).

20. The sputtering target assembly of claim 17 wherein the elastomer layer includes a thermal promoter means for facilitating the transfer of heat from the sputtering target to the backing plate when the sputtering target assembly is in operation.

21. The sputtering target assembly of claim 20 wherein the thermal promoter means comprises one or more pieces of metal screen imbedded in the elastomer layer.

22. The sputtering target assembly of claim 21 wherein the thermal promoter means also includes a plurality of metal particles embedded in the elastomer layer.

23. The sputtering target assembly of claim 17 wherein the sputtering target comprises a material selected from the group consisting of an elemental metal, a metal alloy and ceramics.
